(19) United States
(12) Patent Application Publication
(10) Pub. No.: US 2026/0032843 A1
(43) Pub. Date: Jan. 29, 2026

(54) CHASSIS DESIGN FOR IMPROVED FIT AND THERMAL MANAGEMENT

(71) Applicant: Hamilton Sundstrand Corporation, Charlotte, NC (US)

(72) Inventors: Alexander Trotman, Granby, CT (US); David Dickie, Granby, CT (US)

(21) Appl. No.: 18/785,502

(22) Filed: Jul. 26, 2024

(51) Int. Cl. H05K 7/14; H05K 7/20

(52) U.S. Cl. CPC H05K 7/1424; H05K 7/20418

(57) ABSTRACT

Apparatus and associated methods relate to providing space within an electronics enclosure of a predetermined width for Printed Circuit Board (PCB) modules having span dimensions greater than the width of the electronics enclosure. Such PCB modules are received by an electronics card cage configured having first and second pluralities of slide rails. The first and second pluralities of slide rails are located between and aligned with one another along parallel first and second alignment planes, respectively. Each of the first plurality of slide rails is aligned with a corresponding one of the second plurality of slide rails, thereby defining a card slot spanning a span dimension therebetween. The span dimension is directed along an axis intercepting each of the first and second alignment planes at an angle of incidence that is greater than 20 degrees from normal vectors thereto.

### BACKGROUND

Circuit Card Assembly (CCA) modules refer to Printed Circuit Boards (PCBs) that are arranged in card racks of electronics enclosures. These electronics enclosures provide a controlled environment for the CCA modules, protecting components within from moisture, dust, and other contaminants of the external environment. Typically, electrical connectors provide transmission of signals between electronic components withing these electronics enclosures and other electronic components connected to the electronics enclosures via the electrical connectors. Such electronics enclosures typically have openings for a specific number of CCA modules, into or out of these openings, the CCA modules are inserted or extracted, respectively. The CCA modules are typically guided into the electronics enclosures via slide rails at two opposite sides of the electronics enclosures. These slide rails are part of the card racks that provide mechanical integrity and facilitate electrical interconnectivity between the CCA modules of the electronics enclosures. One or more electrical connectors at a backplane of the electronics enclosure receive corresponding electrical connectors of the CCA modules. Electrical connections between the CCA modules, and even additional circuitry, are often provided by a PCB of the backplane. Such a backplane PCB provides the electronics that interconnect the various CCA modules in a desired way. In some embodiments, instead of a backplane PCB, a cabling assembly and/or electrical connectors simply provide interconnection with a remote electronic system.

Various standards govern various CCA modules, such as, for example, VITA. Such standards specify physical dimensions of CCA modules, locations of card interfaces, etc. The VITA standards provide for three different widths (i.e., the dimension of the CCA module between the slide rails): 3U, 6U, and 9U. A 3U CCA module is 100 mm in width, a 6U CCA module is 233 mm in width, and a 9U CCA module is 360 mm in width. Such standards provide for various sizes of CCA modules. Because these widths between the slide rails are so different, typically differently sized CCA modules use different sized electronics enclosures. In this way, an electronics enclosure can have a simple orthorhombic shape (i.e., having a rectangular cross section in each of the primary cross-sectional directions). Thus, when a system designer selects a specific one of the standardized sizes, the electronics enclosure corresponding to that selected size is typically used to house the system. Should a system designer select more than one of the standardized sizes, typically multiple electronics enclosures will be used for the system, at least one electronics enclosure for each size selected.

Heat dissipation is another consideration of the system designer, for powered CCA modules can generate significant heat. To dissipate the heat generated by the CCA modules within assemblies, sides of the electronics enclosures are often open or filled with apertures so that ambient air can freely move through the electronics enclosures housing the CCA modules, thereby convectively cooling the PCBs. For some applications, however, electronics enclosures are sealed so as to prevent ambient air from entering therein. For example, when designed to operate in harsh environments, sensitive CCA modules are isolated therefrom by sealed electronics enclosures.

### SUMMARY

Some embodiments relate to a Circuit Card Assembly (CCA) module including a card cage within an electronics enclosure, the card cage including first and second pluralities of slide rails. The first plurality of slide rails is proximate, is coupled to, or forms a part of a first side of the electronics enclosure. The second plurality of slide rails is proximate, coupled to, or forms a part of a second side of the electronics enclosure. The first and second sides of the electronics enclosure are opposite and parallel with one another. Each of the first plurality of slide rails is aligned with a corresponding one of the second plurality of slide rails, thereby defining a card slot spanning a span dimension therebetween. Each of the plurality of card slots is configured to receive a Printed Circuit Board (PCB) module therein. The span dimension of each of the card slots is directed along an axis intercepting each of the first and second sides of the electronics enclosure at an angle of incidence that is greater than 20 degrees from normal vectors thereto.

Some embodiments relate to a card cage configured to receive a plurality of Printed Circuit Board (PCB) modules therewithin. The card cage includes first and second pluralities of slide rails. The slide rails of the first plurality of slide rails are aligned with one another along a first alignment plane. The slide rails of the second plurality of slide rails are aligned with one another along a second alignment plane. The first and second alignment planes are parallel to one another. The first and second pluralities of slide rails are between the first and second alignment planes. Each of the first plurality of slide rails is aligned with a corresponding one of the second plurality of slide rails, thereby defining a card slot spanning a span dimension therebetween. Each of the plurality of card slots is configured to receive a Printed Circuit Board (PCB) module therein. The span dimension is greater than a distance between the first and second alignment planes.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIGS. 1A and 1B are perspective views of example CCA modules.

FIGS. 2A and 2B are plan views of electronics enclosures for the CCA modules depicted in FIGS. 1A and 1B, respectively.

FIGS. 3A and 3B are perspective views of an electronics enclosure that is configured to CCA modules having a dimension larger than the width of the enclosure.

FIG. 3C is a plan view of the electronics enclosure depicted in FIGS. 3A and 3B.

FIGS. 4A AND 4B are plan views of an electronics enclosure configured for 3U-standard PCB modules, and an electronics enclosure similarly sized but configured to receive 6U-standard PCB modules, respectively.

FIGS. 5A AND 5B are plan views of electronics enclosures configured for 6U standard CCU modules, with various capabilities for heat dissipation.

### DETAILED DESCRIPTION

Apparatus and associated methods relate to providing space within an electronics enclosure of a predetermined width for Printed Circuit Board (PCB) modules having span dimensions greater than the width of the electronics enclosure. Such PCB modules are received by an electronics card cage configured having first and second pluralities of slide rails. The first and second pluralities of slide rails are located between and aligned with one another along parallel first and second alignment planes, respectively. Each of the first plurality of slide rails is aligned with a corresponding one of the second plurality of slide rails, thereby defining a card slot spanning a span dimension therebetween. The span dimension is directed along an axis intercepting each of the first and second alignment planes at an angle of incidence that is greater than 20 degrees from normal vectors thereto.

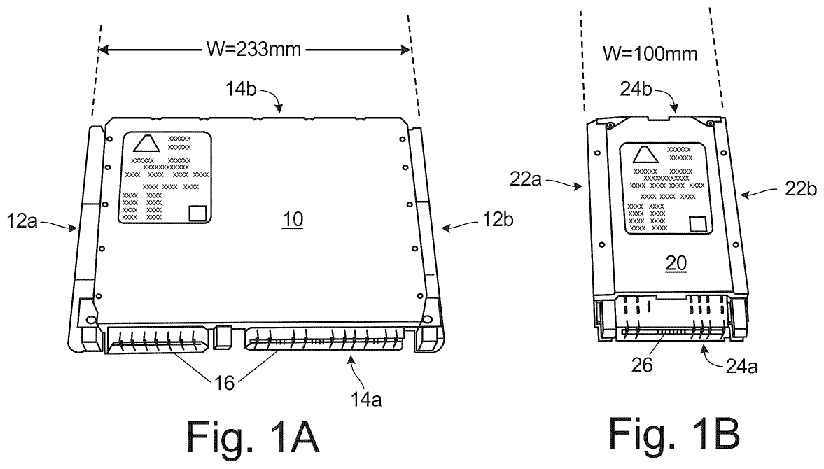

As described above, various standard size CCA modules can be accommodated within an electronics enclosure, but typically an electronics enclosure is designed to receive CCA modules that all have the same width. For example, an electronics enclosure can be designed to receive a predetermined number N of PCB modules, each of standard width W_{PCB}. Thus, all the PCB modules received within the electronics enclosure have the same width W. FIGS. 1A and 1B are perspective views of example PCB modules. In FIG. 1A, PCB module 10 conforms to the VITA 6U standard for PCB modules. The card width W_{PCB} specified by the VITA 6U standard is 233 mm. To conform with this standard, PCB module 10 has lateral sides 12a and 12b which are opposite one another. Distance between opposite lateral sides 12a and 12b define a width W_{PCB} of PCB module 10. Lateral sides 12a and 12b are configured to slidably engage complimentary slide engagement members (e.g., slide rails or card guides) on opposite lateral sides of a card cage configured to receive PCB module 10. PCB module 10 is typically inserted into the electronics enclosure via an opening, which can be exposed by removing a removable cover. PCB module 10 is typically inserted through the opening and into the electronics enclosure, connector side 14a. Typically, a user inserts PCB module 10 while holding side 14b, which is opposite connector side 14a, and guiding sides 12a and 12b into complementary slide engagement members on the opposite lateral sides of the electronics enclosure. PCB module 10 is then guided by such complementary slide engagement members so as to align electrical connector(s) 16 of PCB module 10 with a complementary electrical connector(s) located at a backplane face of the electronics enclosure. The user then continues inserting PCB module 10 until electrical connector(s) 16 of PCB module 10 makes mechanical and electrical connection with the complementary connector(s) located at a backplane face of the electronics enclosure. Often such a connection is accompanied by an audible indication of connection.

In FIG. 1B, PCB module 20 conforms to the VITA 3U standard for PCB modules. The card width W_{PCB} specified by the VITA 3U standard is 100 mm, which is less than one-half of the card width (i.e., 233 mm) specified by the VITA 6U standard. To conform with this VITA 3U standard, PCB module 20 has lateral sides 22a and 22b which are opposite one another. Distance between opposite lateral sides 22a and 22b define a width W_{PCB} of PCB module 20. Sides 22a and 22b are configured to slidably engage complimentary slide engagement members on opposite lateral sides of a card cage configured to receive PCB module 20. Again, PCB module 20 is typically inserted into the electronics enclosure by inserting connector side 24a into the card cage, while engaging lateral sides 22a and 22b with the complementary slide engagement members on opposite lateral sides of the card cage. Typically, a user inserts PCB module 20 while holding side 24b, which is opposite connector side 24a, and guiding sides 22a and 22b into complementary slide engagement members on the opposite lateral sides of the electronics enclosure. The user continues to insert PCB module 20 until connector(s) 26, located at connector side 24a, makes mechanical and electrical connection with a complementary connector located at a backplane face of the electronics enclosure.

Although PCB modules 10 and 20 are shown as adhering to VITA standards, CCA modules adhering to various other standards can be accommodated by the methods and apparatus disclosed herein.

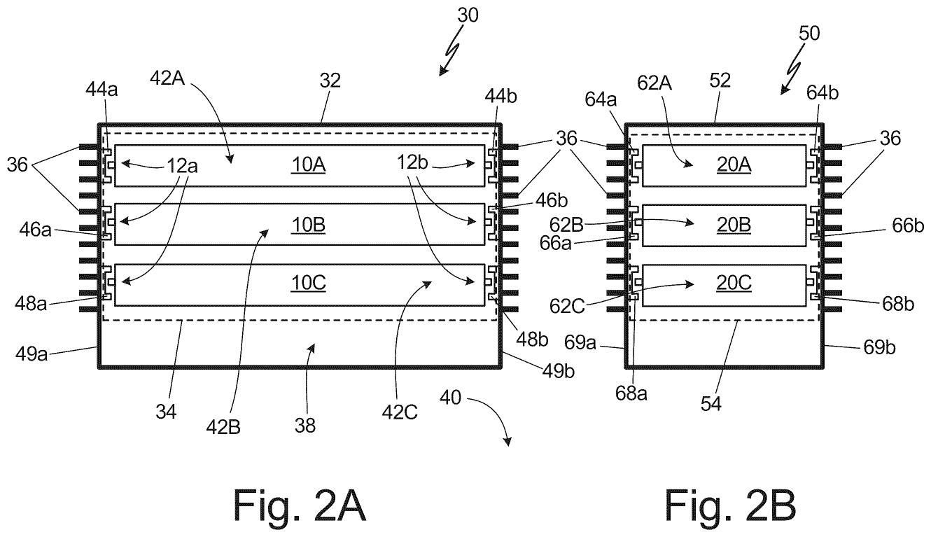

FIGS. 2A and 2B are plan views of CCA assemblies for the PCB modules depicted in FIGS. 1A and 1B, respectively. In FIG. 2A, CCA assembly 30 includes electronics enclosure 32, card cage 34, and external fins 36. In some applications, CCA assembly 30 is located in an environment that can be harmful to sensitive electronic equipment. In such applications, electronics enclosure 32 can sealably isolate interior cavity 38 from exterior environment 40, thereby protecting any sensitive electronic components therewithin from harmful exterior environment 40. Isolating interior cavity 38 from exterior environment 40, however, makes cooling of the sensitive electronic equipment more difficult, as the air from exterior environment 40 cannot be used as a fluid for direct convective cooling of the electronic equipment housed within electronics enclosure 32. To facilitate cooling of electronic equipment housed within electronics enclosure 32, electronics enclosure 32 has external fins 36 projecting from an exterior surface of electronics enclosure 32.

Card cage 34 has three card slots 42A, 42B and 42C, which are defined between corresponding pairs of slide members 44a and 44b, 46a and 46b, and 48a and 48b, respectively. Each of card slots 42A, 42B and 42C are configured to receive PCB modules between these corresponding pairs of slide members 44a and 44b, 46a and 46b, and 48a and 48b, respectively, which are located on opposite lateral sides 49a and 49b of card cage 34. Slide members 44a, 46a, and 48a are aligned with one another along first alignment plane P_{A1} of card cage 34. Slide members 44b, 46b, and 48b are aligned with one another along second alignment plane P_{A2} of card cage 34. Alignment of slide members 44a, 46a, and 48a along first alignment plane P_{A1} of card cage 34 permits slide members 44a, 46a, and 48a to be proximate, coupled to, or form a part of a first side 49a, which is similarly substantially planar, of electronics enclosure 32. Similarly, alignment of slide members 44b, 46b, and 48b along second alignment plane P_{A2} of card cage 34 permits slide members 44b, 46b, and 48b to be proximate, coupled to, or form a part of a second side 49b, which is similarly substantially planar, of electronics enclosure 32. Thus, first and second alignment planes P_{A1} and P_{A2} of card cage 34 are substantially parallel to first and second lateral sides 49a and 49b.

Distances between such pairs of slide members 44a and 44b, 46a and 46b, and 48a and 48b define a span dimension D_{SPAN} of PCB modules that can be received within card cage 34. For card cage 34, as depicted in FIG. 2A, the span dimension D_{SPAN} corresponds to the width W=233 mm of PCB module 10 (as depicted in FIG. 1A) adhering to the VITA 6U standard. In FIG. 2A, card cage 34 of CCA assembly 30, is shown as having PCB modules 10A, 10B, and 10C received within card slots 42A, 42B, and 42C, respectively. The span dimension D_{SPAN} is aligned with an axis A that intercepts first and second alignment planes P_{A1} and P_{A2} of card cage 34 at an angle of incidence θ_{INCIDENCE} of approximately zero degrees with respect to normal vectors thereto. Because first and second alignment planes P_{A1} and P_{A2} are substantially parallel to first and second lateral sides 49a and 49b, span dimension D_{SPAN} is aligned with an axis A that also intercepts first and second lateral sides 49a and 49b at an angle of incidence θ_{INCIDENCE} of approximately zero degrees with respect to normal vectors thereto.

Each of PCB modules 10A, 10B, and 10C have been received within card cage 34 by slidably guiding PCB modules 10A, 10B, and 10C into card cage 34. For example, PCB module 10A is slidably guided into card cage 34 by slidably engaging opposite lateral sides 12a and 12b of PCB module 10A with complimentary slide engagement members 44a and 44b on opposite lateral sides of card cage 34. Similarly, PCB modules 10B is slidably guided into card cage 34 by slidably engaging opposite lateral sides 12a and 12b of PCB module 10B with complimentary slide engagement members 46a and 46b on opposite lateral sides of card cage 34. And again, PCB modules 10C is slidably guided into card cage 34 by slidably engaging opposite lateral sides 12a and 12b of PCB module 10C with complimentary slide engagement members 48a and 48b on opposite lateral sides of card cage 34.

In FIG. 2B, CCA assembly 50 includes electronics enclosure 52, card cage 54, and external fins 36. In the embodiment depicted in FIG. 2B, card cage 54 has three card slots 62A, 62B and 62C, which are defined between corresponding pairs of slide members 64a and 64b, 66a and 66b, and 68a and 68b, respectively. Each of card slots 62A, 62B and 62C are configured to receive PCB modules between these corresponding pairs of slide members 64a and 64b, 66a and 66b, and 68a and 68b, respectively. which are located on opposite lateral sides 69a and 69b of card cage 52. Slide members 64a, 66a, and 68a are aligned with one another along first alignment plane P_{A1} of card cage 52. Slide members 64b, 66b, and 68b are aligned with one another along second alignment plane P_{A2} of card cage 52. Distances between such pairs of slide members 64a and 64b, 66a and 66b, and 68a and 68b define span a dimension D_{SPAN} of PCB modules that can be received within card cage 52. For card cage 52, as depicted in FIG. 2B, the span dimension D_{SPAN} corresponds to the width W=100 mm of PCB module 10 (as depicted in FIG. 1B) adhering to the VITA EU standard. In FIG. 2B, card cage 52 of CCA assembly 50, is shown as having PCB modules 20A, 20B, and 20C received within card slots 62A, 62B and 62C, respectively. Electronics enclosure 52 is designed to accommodate only PCB modules, such as PCB modules 20A, 20B, and 20C, that adhere to such a VITA 3U standard. The span dimension D_{SPAN} is aligned with an axis A that intercepts opposite lateral sides 69a and 69b at an angle of incidence θ_{INCIDENCE} of approximately zero degrees with respect to normal vectors thereto. In other words, PCB modules 20A, 20B, and 20C are oriented substantially perpendicular with opposite lateral sides 69a and 69b.

Each of PCB modules 20A, 20B, and 20C have been received within card cage 54 by slidably guiding PCB modules 20A, 20B, and 20C into card cage 54. For example, PCB module 20A is slidably guided into card cage 54 by slidably engaging opposite lateral sides 22a and 22b of PCB module 20A with slide engagement members 64a and 64b on opposite lateral sides of card cage 54. Similarly, PCB module 20B is slidably guided into card cage 54 by slidably engaging opposite lateral sides 22a and 22b of PCB module 20B with complimentary slide engagement members 66a and 66b on opposite lateral sides of card cage 54. And again, PCB modules 20C is slidably guided into card cage 54 by slidably engaging opposite lateral sides 22a and 22b of PCB module 20C with complimentary slide engagement members 68a and 68b on opposite lateral sides of card cage 54.

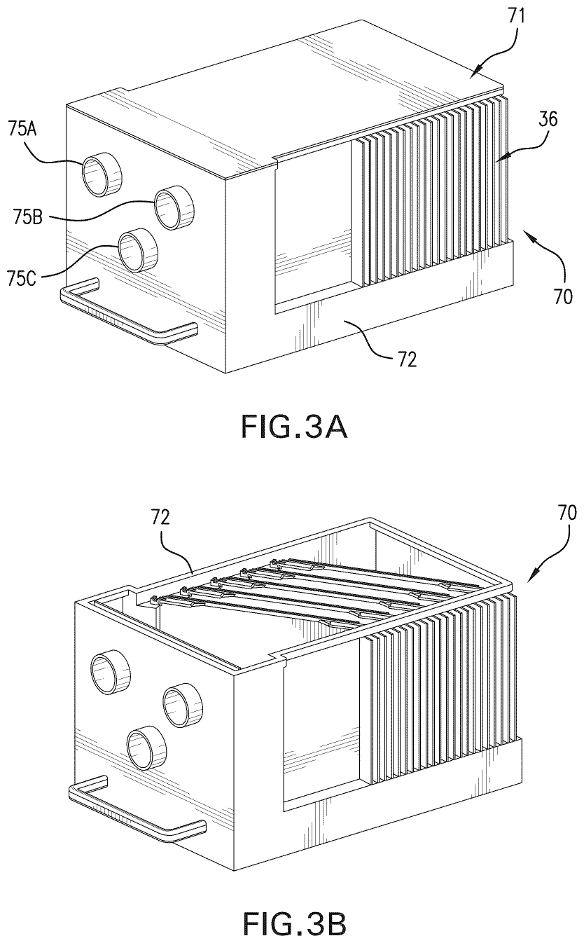

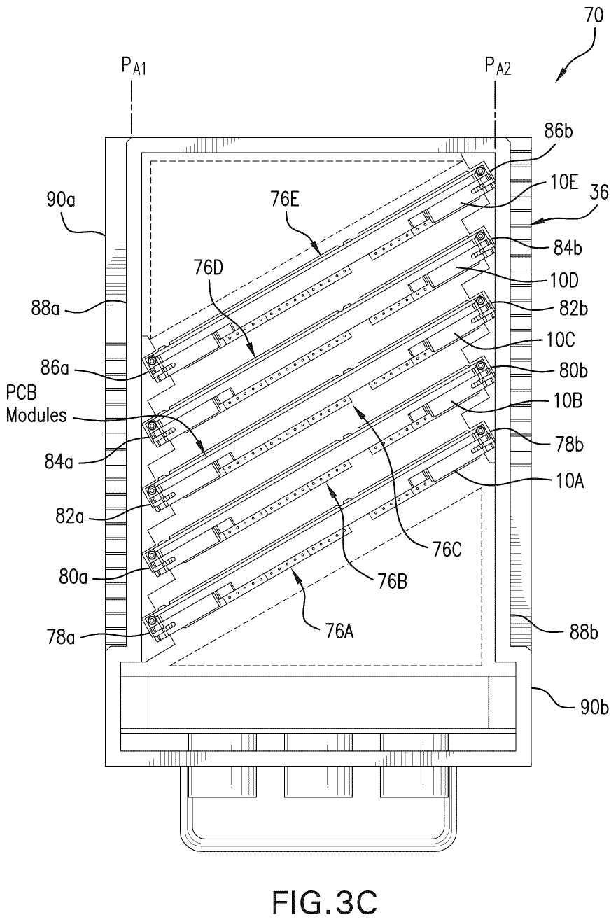

FIGS. 3A and 3B are perspective views of an electronics enclosure that is configured to PCB modules having a dimension larger than the width of the enclosure. FIG. 3C is a plan view of the electronics enclosure depicted in FIGS. 3A and 3B. In FIGS. 3A-3C, CCA assembly 70 is depicted with cover 71 in place and removed, respectively. CCA assembly 70 includes electronics enclosure 72, card cage 74, cooling fins 36, and electrical connectors 75A-75C. Card cage 74 is located within electronics enclosure 72 and has card slots 76A-76E defined between pairs of slide rails 78 a and b, 80 a and b, 82 a and b, 84 a and b, 86 a and b, respectively. The a-designated slide rails of each pair, 78a, 80a, 82a, 84a, and 86a, are aligned with one another along an alignment plane P_{A1}. Similarly, the b-designated slide rails of each pair, 78b, 80b, 82b, 84b, and 86b, are aligned with one another along an alignment plane P_{A2}. Such alignment planes P_{A1} and P_{A2} define opposite lateral sides 88a and 88b of card cage 74. Opposite lateral sides 88a and 88b are parallel with one another such that card cage 74 can be situated within electronics enclosure 72 having parallel opposite lateral sides 90a and 90b.

Each of the first plurality of a-designated slide rails, 78a, 80a, 82a, 84a, and 86a, is aligned with a corresponding one of the second plurality of b-designated slide rails, 78b, 80b, 82b, 84b, and 86b, thereby defining a card slot, 78A, 78B, 78C, 78D, and 78E, respectively. Each of card slots 78b, 80b, 82b, 84b, and 86b, spans a span dimension D_{SPAN} between its pair of slide rails, 78 a and b, 80 a and b, 82 a and b, 84 a and b, 86 a and b, respectively. each of the plurality of card slots configured to receive a PCB module 10A-10E therein. The span dimension D_{SPAN} is directed along an axis X_{A}-X_{E} intercepting each of the first and second sides 90a and 90b of electronics enclosure 72 at an angle of incidence θ_{INCIDENCE} that is greater than 20 degrees from normal vectors thereto. Because of this non-zero angle of incidence θ_{INCIDENCE}, the card cage 74 can receive PCB modules 10A-10E that have a card width W_{PCB} that is greater than a distance between the first and second alignment planes. Therefore, electronics enclosure 72 can receive PCB modules 10A-10E that have a card width W_{PCB} greater than a distance of separation between opposite lateral sides 90a and 90b of electronics enclosure 72.

By such angling of PCB modules 10A-10E within electronics enclosure 72, a lateral dimension of electronics enclosure 72 can be either reduced (i.e., made narrower than the card width W_{PCB}) or used for cooling purposes (e.g., cooling fins can be located on exterior surfaces of the opposite lateral sides 90a and 90b). In the embodiment depicted in FIGS. 3A and 3B, opposite lateral sides 90a and 90b have a recessed portion, in which cooling fins 36 are situated. Cooling fins 36 extend from the exterior surfaces of opposite lateral sides 90a and 90b a distance commensurate with the exterior surfaces of the un-recessed portions of opposite lateral sides 90a and 90b, thereby wholly residing within a width dimension W_{ENCLOSURE} of electronics enclosure 72. For scenarios in which space is limited, the width dimension W_{ENCLOSURE} of electronics enclosure 72 can be made narrower than the card width W_{PCB} of PCB modules 10A-10E residing within electronics enclosure 72. Because of the angling of PCB modules 10A-10E, space at a front and back end within electronics enclosure 72 exists, which can be used for additional, albeit narrower PCB modules, other electrical or electronics components, cooling fans, etc.

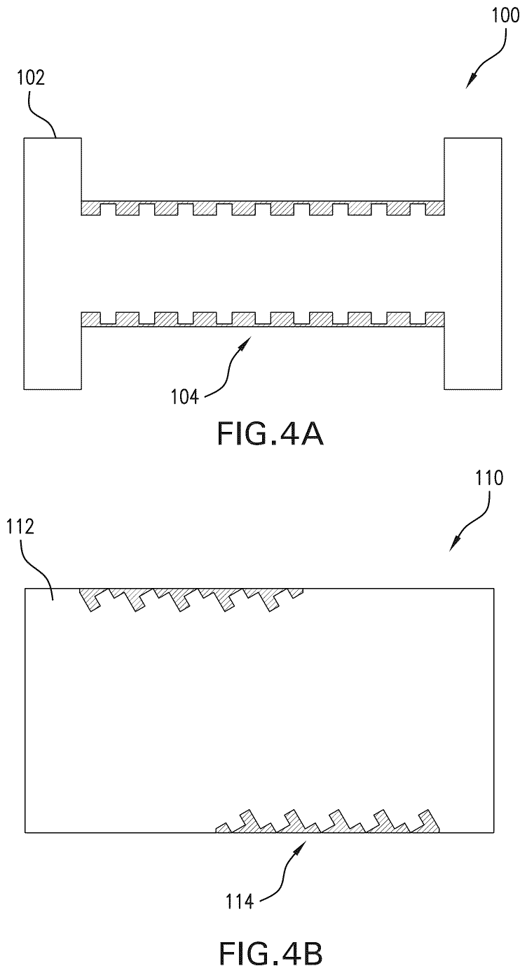

FIGS. 4A AND 4B are plan views of an electronics enclosure configured for 3U-standard PCB modules, and an electronics enclosure similarly sized but configured to receive 6U-standard PCB modules, respectively. In FIG. 4A, standard-sized CCA assembly 100 is depicted. CCA assembly 100 is configured to receive up to nine 3U-standard VITA PCB modules. CCA assembly 100 has electronics enclosure 102 with a width dimension W_{ENCLOSURE} of 8.5 inches. Card cage 104 is located within electronics enclosure 102 and has a length dimension L_{CARD-CAGE} of 12 inches. In FIG. 4B, CCA assembly 110 is depicted. CCA assembly 110 is configured to receive up to five 6U-standard VITA PCB modules. CCA assembly 110 has electronics enclosure 112 with a width dimension W_{ENCLOSURE} of 8.5 inches—the same width dimension of CCA assembly 100 depicted in FIG. 4A. Card cage 114 is located within electronics enclosure 112 and has a length dimension L_{CARD-CAGE} of 12 inches—again the same length dimension of CCA assembly 100 depicted in FIG. 4A. Because the width W_{PCB} of a 6U-standard VITA PCB module is more than twice the width W_{PCB} of a 3U-standard VITA PCB module, more electronics can be housed within CCA assembly 110 than can be housed with CCA assembly 100. For example, a ratio of the amount of electronics that can be housed within CCA assembly 110 to that of CCA assembly 100 is approximately 5·233/9·100≈1.3. Moreover, additional space resides at the front and back ends within electronics enclosure 110.

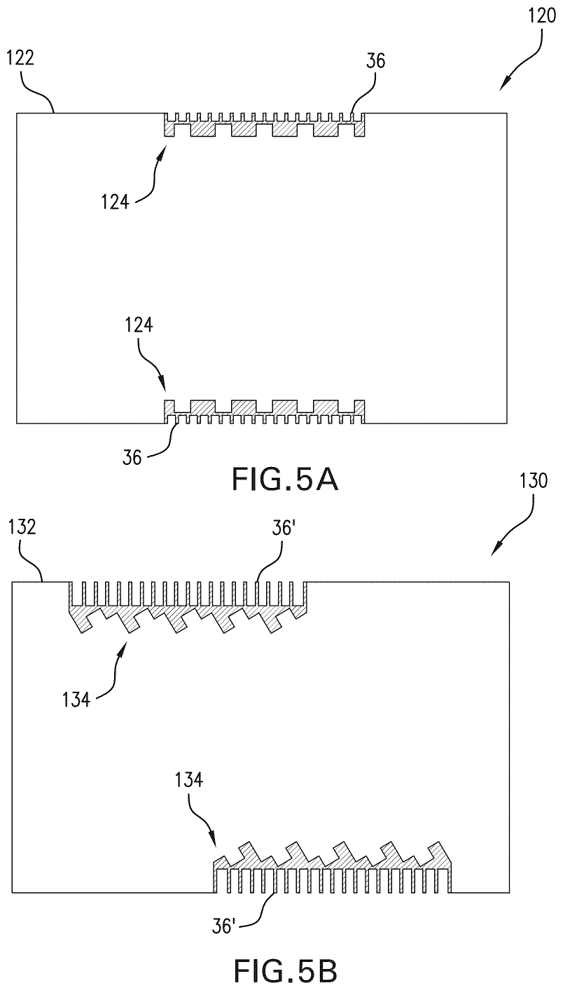

FIGS. 5A AND 5B are plan views of electronics enclosures configured for 6U-standard CCU modules, with various capabilities for heat dissipation. In FIG. 5A, standard-sized CCA assembly 120 is depicted. CCA assembly 120 is configured to receive up to five 6U-standard VITA PCB modules. CCA assembly 120 has electronics enclosure 122 with a width dimension W_{ENCLOSURE} of 10 inches. Card cage 124 is located within electronics enclosure 122 and is thermally coupled with cooling fins 36 on exterior surfaces of opposite lateral walls 126a and 126b. In FIG. 5B, CCA assembly 130 is depicted. CCA assembly 130 is configured to receive up to five 6U-standard VITA PCB modules. CCA assembly 130 has electronics enclosure 132 with a width dimension W_{ENCLOSURE} of 10 inches—the same width dimension of CCA assembly 120 depicted in FIG. 5A. Card cage 134 is located within electronics enclosure 132 and is thermally coupled with cooling fins 36′ on exterior surfaces of opposite lateral walls 136a and 136b. Cooling fins 36′ of CCA assembly 130 extend from the exterior surfaces of opposite lateral walls 136a and 136b much further than cooling fins 36 of CCA assembly 120 extend from the exterior surfaces of opposite lateral walls 126a and 126b. This is made possible by angling the 6U-standard VITA PCB modules within electronics enclosure 132.

### Discussion of Possible Embodiments

The following are non-exclusive descriptions of possible embodiments of the present invention.

Some embodiments relate to a Circuit Card Assembly (CCA) module that includes a card cage within an electronics enclosure. The card cage has a first plurality of slide rails proximate, coupled to, or forming a part of a first side of the electronics enclosure and a second plurality of slide rails proximate, coupled to, or forming a part of a second side of the electronics enclosure. The first and second sides of the electronics enclosure are opposite to and parallel with one another. Each of the first plurality of slide rails is aligned with a corresponding one of the second plurality of slide rails, thereby defining a card slot spanning a span dimension therebetween. Each of the plurality of card slots configured to receive a Printed Circuit Board (PCB) module therein, the span dimension of each of the card slots being directed along an axis intercepting each of the first and second sides of the electronics enclosure at an angle of incidence that is greater than 20 degrees from normal vectors thereto.

The CCA module of the preceding paragraph can optionally include, additionally and/or alternatively, any one or more of the following features, configurations, and/or additional components:

A further embodiment of the foregoing CCA module, wherein the angle of incidence can be greater than 30 degrees.

A further embodiment of any of the foregoing CCA modules, wherein the angle of incidence can be greater than 40 degrees.

A further embodiment of any of the foregoing CCA modules, wherein a separation distance between the first and second sides of the electronics enclosure can be less than the span dimension of each of the card slots defined between corresponding ones of the first and second pluralities of slide rails.

A further embodiment of any of the foregoing CCA modules, wherein a ratio of the span dimension to the separation distance between the first and second sides can be greater than 120%.

A further embodiment of any of the foregoing CCA modules, wherein a ratio of the span dimension to the separation distance between the first and second sides can be greater than 130%.

A further embodiment of any of the foregoing CCA modules, wherein a ratio of the span dimension to the separation distance between the first and second sides can be greater than 140%.

A further embodiment of any of the foregoing CCA modules can further include a heat sink on an exterior surface of the first side of the electronics enclosure, the heat sink opposite to and thermally coupled with the first plurality of slide rails.

A further embodiment of any of the foregoing CCA, wherein the heat sink can be a first heat sink. The electronics enclosure can further include a second heat sink on an exterior surface of the second side of the electronics enclosure, the second heat sink opposite to and thermally coupled with the second plurality of slide rails.

A further embodiment of any of the foregoing CCA modules, wherein the side walls can have recesses within which the first and second heat sinks are located.

A further embodiment of any of the foregoing CCA modules, wherein each of the first and second heat sinks and the first and second pluralities of slide rails, respectively, can be formed as a unitary body.

A further embodiment of any of the foregoing CCA modules, wherein first and second heat sinks can extend from a bottom side of the enclosure to a top side of the enclosure.

A further embodiment of any of the foregoing CCA modules, wherein each of the first and second heat sinks has a plurality of vertical fins facilitating airflow from a bottom to a top of each of the first and second heat sinks.

A further embodiment of any of the foregoing CCA modules can further include a removable cover that removably covers an opening through which a CCA module(s) can be inserted into and/or removed from the electronics enclosure.

A further embodiment of any of the foregoing CCA modules can further include a backplane on a side of the electronics enclosure opposite the opening. The backplane can have connectors configured to connect to any CCA module(s) inserted into the electronics enclosure and guided to a corresponding one of the connectors of the backplane by the corresponding ones of the first and second slide rails.

Some embodiments relate to a card cage configured to receive a plurality of Printed Circuit Board (PCB) modules therewithin. The card cage includes a first plurality of slide rails aligned with one another along a first alignment plane and a second plurality of slide rails aligned with one another along a second alignment plane, the first and second alignment planes parallel to one another. The first and second pluralities of slide rails are between the first and second alignment planes. Each of the first plurality of slide rails is aligned with a corresponding one of the second plurality of slide rails, thereby defining a card slot spanning a span dimension therebetween. Each of the plurality of card slots is configured to receive a Printed Circuit Board (PCB) module therein. The span dimension being greater than a distance between the first and second alignment planes.

The card cage of the preceding paragraph can optionally include, additionally and/or alternatively, any one or more of the following features, configurations, and/or additional components:

A further embodiment of the foregoing card cage, wherein a ratio of the span dimension to the distance between the first and second alignment planes can be greater than 120%.

A further embodiment of any of the foregoing card cages, wherein a ratio of the span dimension to the distance between the first and second alignment planes can be greater than 130%.

A further embodiment of any of the foregoing card cages, wherein the span dimension can be directed along an axis intercepting each of the first and second alignment planes at an angle of incidence that is greater than 20 degrees from normal vectors thereto.

A further embodiment of any of the foregoing card cages, wherein the angle of incidence can be greater than 30 degrees.

It will be recognized that the invention is not limited to the implementations so described but can be practiced with modification and alteration without departing from the scope of the appended claims. For example, the above implementations may include specific combinations of features. However, the above implementations are not limited in this regard, and, in various implementations, the above implementations may include the undertaking only a subset of such features, undertaking a different order of such features, undertaking a different combination of such features, and/or undertaking additional features than those features explicitly listed. The scope of the invention should, therefore, be determined with reference to the appended claims, along with the full scope of equivalents to which such claims are entitled.

1. A Circuit Card Assembly (CCA) module comprising:
an electronics enclosure; and
a card cage within the electronics enclosure, the card cage including:
a first plurality of slide rails proximate, coupled to, or forming a part of a first side of the electronics enclosure; and
a second plurality of slide rails proximate, coupled to, or forming a part of a second side of the electronics enclosure, the first and second sides of the electronics enclosure opposite to and parallel with one another,
wherein each of the first plurality of slide rails is aligned with a corresponding one of the second plurality of slide rails, thereby defining a card slot spanning a span dimension therebetween, each of the plurality of card slots configured to receive a Printed Circuit Board (PCB) module therein, the span dimension of each of the card slots being directed along an axis intercepting each of the first and second sides of the electronics enclosure at an angle of incidence that is greater than 20 degrees from normal vectors thereto.

2. The CCA assembly of claim 1, wherein the angle of incidence is greater than 30 degrees.

3. The CCA assembly of claim 2, wherein the angle of incidence is greater than 40 degrees.

4. The CCA assembly of claim 1, wherein a separation distance between the first and second sides of the electronics enclosure is less than the span dimension of each of the card slots defined between corresponding ones of the first and second pluralities of slide rails.

5. The CCA assembly of claim 4, wherein a ratio of the span dimension to the separation distance between the first and second sides is greater than 120%.

6. The CCA assembly of claim 5, wherein a ratio of the span dimension to the separation distance between the first and second sides is greater than 130%.

7. The CCA assembly of claim 6, wherein a ratio of the span dimension to the separation distance between the first and second sides is greater than 140%.

8. The CCA assembly of claim 1, further comprising:
a heat sink on an exterior face of the first side of the electronics enclosure, the heat sink opposite to and thermally coupled with the first plurality of slide rails.

9. The CCA assembly of claim 8, wherein the heat sink is a first heat sink, the electronics enclosure further comprising:
a second heat sink on an exterior face of the second side of the electronics enclosure, the second heat sink opposite to and thermally coupled with the second plurality of slide rails.

10. The CCA assembly of claim 9, wherein the side walls have recesses within which the first and second heat sinks are located.

11. The CCA assembly of claim 9, wherein each of the first and second heat sinks and the first and second pluralities of slide rails, respectively, are formed as a unitary body.

12. The CCA assembly of claim 9, wherein first and second heat sinks extend from a bottom side of the enclosure to a top side of the enclosure.

13. The CCA assembly of claim 11, wherein each of the first and second heat sinks has a plurality of vertical fins facilitating airflow from a bottom to a top of each of the first and second heat sinks.

14. The CCA assembly of claim 1, further comprising a removable cover that removably covers an opening through which a CCA module(s) can be inserted into and/or removed from the electronics enclosure.

15. The CCA assembly of claim 14, further comprising:
a backplane on a side of the electronics enclosure opposite the opening, the backplane having connectors configured to connect to any CCA module(s) inserted into the electronics enclosure and guided to a corresponding one of the connectors of the backplane by the corresponding ones of the first and second slide rails.

16. A card cage configured to receive a plurality of Printed Circuit Board (PCB) modules therewithin, the card cage including:
a first plurality of slide rails aligned with one another along a first alignment plane; and
a second plurality of slide rails aligned with one another along a second alignment plane, the first and second alignment planes parallel to one another, wherein the first and second pluralities of slide rails are between the first and second alignment planes,
wherein each of the first plurality of slide rails is aligned with a corresponding one of the second plurality of slide rails, thereby defining a card slot spanning a span dimension therebetween, each of the plurality of card slots configured to receive a Printed Circuit Board (PCB) module therein, the span dimension being greater than a distance between the first and second alignment planes.

17. The card cage of claim 16, wherein a ratio of the span dimension to the distance between the first and second alignment planes is greater than 120%.

18. The card cage of claim 17, wherein a ratio of the span dimension to the distance between the first and second alignment planes is greater than 130%.

19. The card cage of claim 16, wherein the span dimension is directed along an axis intercepting each of the first and second alignment planes at an angle of incidence that is greater than 20 degrees from normal vectors thereto.

20. The card cage of claim 19, wherein the angle of incidence is greater than 30 degrees.
